(19) United States
(12) Patent Application Publication
(10) Pub. No.: US 2025/0077745 A1
(43) Pub. Date: Mar. 6, 2025

(54) INFORMATION PROCESSING APPARATUS, INFORMATION PROCESSING METHOD, AND PROGRAM

(71) Applicant: NEC Corporation, Tokyo (JP)

(72) Inventors: Joe BRINTON, Tokyo (JP); Yutaka Yakuwa, Tokyo (JP)

(73) Assignee: NEC Corporation, Tokyo (JP)

(21) Appl. No.: 18/810,794

(22) Filed: Aug. 21, 2024

(30) Foreign Application Priority Data
Sep. 1, 2023 (JP) 2023-142271

(51) Int. Cl. G06F 30/27; G06F 30/18

(52) U.S. Cl. CPC G06F 30/27; G06F 30/18

(57) ABSTRACT

An information processing apparatus of the present disclosure includes: a designing unit that generates design path information representing a design process of system configuration information designed by converting an abstract element into a concrete element using a concretization rule; a converting unit that generates embedded design path information to which information of a superordinate concept of the element of each system configuration information included in the design path information is added; a reward setting unit that sets a reward for each system configuration information included in the embedded design path information in accordance with whether or not the element of the system configuration information is a concrete element; and a learning data generating unit that generates learning data using each system configuration information included in the embedded design path information and the reward set for the system configuration information.

### INCORPORATION BY REFERENCE

This application is based upon and claims the benefit of priority from Japanese patent application No. 2023-142271, filed on Sep. 1, 2023, the disclosure of which is incorporated herein in its entirety by reference.

### TECHNICAL FIELD

The present disclosure relates to an information processing apparatus, an information processing method, and a program.

### BACKGROUND ART

When designing an ICT (Information and Communication Technology) system, first, in requirements definition, the designer creates system requirements, which are information summarizing customer's requirements. At this time, system requirements generally include abstract information and often do not represent a deployable system configuration as they are. Therefore, the designer concretizes stepwise the abstract information included in the system requirements and designs a deployable system configuration in which all the information are concrete finally.

Since this series of actions requires expertise in elements included in a system configuration and the relation between the elements, man-hours related to design and necessary human costs increase as a system becomes sophisticated.

As a method for solving the above problem, an automated system design technique has been proposed. The automated system design technique is a technique of automatically deriving a system configuration including only concrete information based on system requirements including abstract information.

As a related technique, Patent Literature 1 discloses a system configuration derivation apparatus that can concretize stepwise abstract parts included in system requirements based on the requirements and derive a deployable and concrete ICT system configuration.

The system configuration derivation apparatus of Patent Literature 1 learns a method for calculating a score representing the degree of adequacy of a concretization rule that is a rule for rewriting in more detail part of configuration requirements representing requirements concerning an ICT system.

When an abstract system requirement is entered, the apparatus having thus learned can select adequate concretization rules and design a concrete system configuration speedily and automatically.
Patent Literature 1: Japanese Patent No. 6989014

However, the technique described in the Patent Literature 1 above does not guarantee accuracy in precision of evaluation by the apparatus for a new element (unlearned element) that does not exist in the past learning process. Therefore, when designing a system using an unlearned element, the apparatus cannot utilize a learning experience concerning a previously learned element for evaluation of the quality of the unlearned element, and cannot perform highly precise system design.

Therefore, the technique described in Patent Literature 1 has a problem that the apparatus needs relearning when it is desired to design a system using a new element, which requires time cost.

### SUMMARY OF THE INVENTION

Accordingly, an object of the present disclosure is to solve the abovementioned problem that time cost is required for system design.

An information processing apparatus as an aspect of the present disclosure includes: a designing unit that generates, for system configuration information each representing a system configuration including a combination of elements, design path information representing a design process of the system configuration information designed by converting an abstract element into a concrete element using a preset concretization rule; a converting unit that generates embedded design path information in which each system configuration information of the system configuration information included in the design path information is provided with information of an element corresponding to a superordinate concept of the element included by the each system configuration information; a reward setting unit that sets, for each system configuration information of the system configuration information included in the embedded design path information, a reward for the each system configuration information in accordance with whether or not the element included by the each system configuration information is a concrete element; and a learning data generating unit that, by using each system configuration information of the system configuration information included in the embedded design path information and the reward set for the each system configuration information, generates learning data to be machine-learned for generating a model that converts the system configuration information based on the concretization rule.

Further, an information processing method as an aspect of the present disclosure includes: generating, for system configuration information each representing a system configuration including a combination of elements, design path information representing a design process of the system configuration information designed by converting an abstract element into a concrete element using a preset concretization rule; generating embedded design path information in which each system configuration information of the system configuration information included in the design path information is provided with information of an element corresponding to a superordinate concept of the element included by the each system configuration information; setting, for each system configuration information of the system configuration information included in the embedded design path information, a reward for the each system configuration information in accordance with whether or not the element included by the each system configuration information is a concrete element; and by using each system configuration information of the system configuration information included in the embedded design path information and the reward set for the each system configuration information, generating learning data to be machine-learned for generating a model that converts the system configuration information based on the concretization rule.

Further, a computer program as an aspect of the present disclosure includes instructions for causing a computer to execute processes to: generate, for system configuration information each representing a system configuration including a combination of elements, design path information representing a design process of the system configuration information designed by converting an abstract element into a concrete element using a preset concretization rule; generate embedded design path information in which each system configuration information of the system configuration information included in the design path information is provided with information of an element corresponding to a superordinate concept of the element included by the each system configuration information; set, for each system configuration information of the system configuration information included in the embedded design path information, a reward for the each system configuration information in accordance with whether or not the element included by the each system configuration information is a concrete element; and by using each system configuration information of the system configuration information included in the embedded design path information and the reward set for the each system configuration information, generate learning data to be machine-learned for generating a model that converts the system configuration information based on the concretization rule.

Configured as described above, the present disclosure can reduce time cost when performing system design.

### BRIEF DESCRIPTION OF DRAWINGS

FIG. 1 is a view for describing automatic design of a system;

FIG. 2 is a view for describing automatic design of the system;

FIG. 3 is a view for describing automatic design of the system;

FIG. 4 is a view for describing automatic design of the system;

FIG. 5 is a view for describing automatic design of the system;

FIG. 6 is a block diagram showing the configuration of an information processing system according to the present disclosure;

FIG. 7 is a flowchart showing the processing operation of the information processing system according to the present disclosure;

FIG. 8 is a flowchart showing the processing operation of the information processing system according to the present disclosure;

FIG. 9 is a flowchart showing the processing operation of the information processing system according to the present disclosure;

FIG. 10 is a view showing an aspect of processing by the information processing system according to the present disclosure;

FIG. 11 is a view showing an aspect of processing by the information processing system according to the present disclosure;

FIG. 12 is a view showing an aspect of processing by the information processing system according to the present disclosure;

FIG. 13 is a flowchart showing the processing operation of the information processing system according to the present disclosure;

FIG. 14 is a view showing an aspect of processing by the information processing system according to the present disclosure;

FIG. 15 is a flowchart showing the processing operation of the information processing system according to the present disclosure;

FIG. 16 is a view showing an aspect of processing by the information processing system according to the present disclosure;

FIG. 17 is a flowchart showing the processing operation of the information processing system according to the present disclosure;

FIG. 18 is a view showing an aspect of processing by the information processing system according to the present disclosure;

FIG. 19 is a view showing an aspect of processing by the information processing system according to the present disclosure;

FIG. 20 is a flowchart showing the processing operation of the information processing system according to the present disclosure;

FIG. 21 is a flowchart showing the processing operation of the information processing system according to the present disclosure;

FIG. 22 is a flowchart showing the processing operation of the information processing system according to the present disclosure;

FIG. 23 is a flowchart showing the processing operation of the information processing system according to the present disclosure;

FIG. 24 is a block diagram showing the hardware configuration of an information processing apparatus according to the present disclosure; and

FIG. 25 is a block diagram showing the configuration of the information processing apparatus according to the present disclosure.

### EXAMPLE EMBODIMENT

### First Example Embodiment

A first example embodiment of the present disclosure will be described with reference to the drawings. The drawings may be relevant to any of the example embodiments.

### Overview

First, the overview of automatic design of an ICT system in this example embodiment will be described. First, the premise is that the requirement and configuration of an ICT system can be expressed with a graph. A graph represents elements (components and the relation between the components) included in the configuration of an ICT system using nodes or edges. A node is an element that represents, for example, a device or an application. An edge is an element that represents a connection relation between two nodes.

As an example of an ICT system, a case of designing a face recognition system will be described. When designing a face recognition system, the designer first creates a system requirement for the face recognition system.

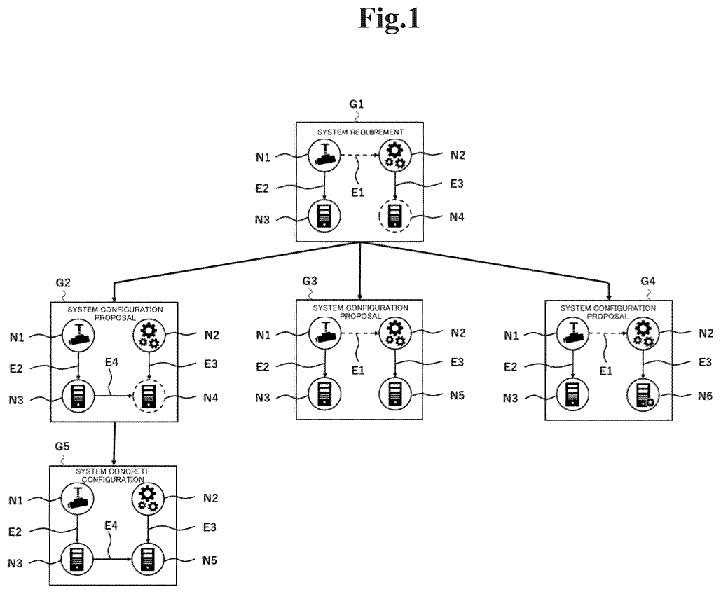

FIG. 1 is a view for describing automatic design of a face recognition system. A graph G1 in FIG. 1 is a graph showing the configuration of a system requirement R1 of the face authentication system. The graph G1 in FIG. 1 is shown using nodes N1, N2, N3 and N4 and edges E1, E2 and E3.

The node N1 represents a camera function as a concrete element (solid-line circle), the node N2 represents a face recognition function as a concrete element (solid-line circle), the node N3 represents a server computer function as a concrete element (solid-line circle), and the node N4 represents a server computer function as an abstract element (dashed circle). The edge E1 represents an HTTP communication function as an abstract element (dashed arrow), and the edges E2 and E3 represent join functions as concrete elements (solid-line arrows). The parts other than the graph G1 (system requirement) in FIG. 1 will be described later.

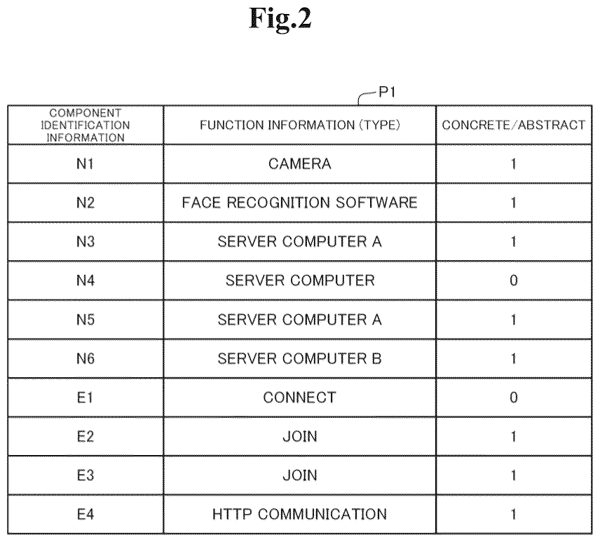

FIG. 2 is a view for explaining the data structure of component information that is information of the abovementioned elements. Component information P1 shown in FIG. 2 associates, for each of the component identification information for identifying nodes and edges, function information (also referred to as type) of the node or edge with information showing whether the node or edge is a concrete component (element) or an abstract component (element) (concrete (1)/abstract (0)).

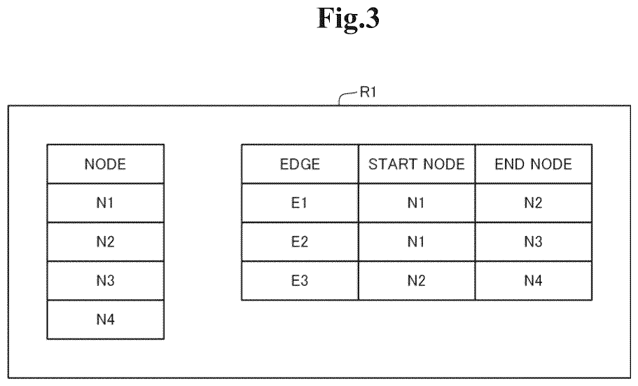

FIG. 3 is a view for explaining the data structure of a system requirement. The system requirement R1 of FIG. 3 is a system requirement corresponding to the graph G1 shown in FIG. 1. The system requirement R1 includes component identification information for identifying all the nodes included in the requirement. Then, the system requirement R1 is information including component identification information for identifying all the edges included in the requirement, component identification information for identifying the node equivalent to the start of the edge, and component identification information for identifying the node equivalent to the end of the edge.

In FIGS. 1 to 3 shown above, a graph, component information, and a system requirement are described using the graph G1, the component information P1, and the system requirement R1, but a graph, component information, and a system requirement are not limited to the graph G1, the component information P1, and the system requirement R1 shown in FIGS. 1 to 3.

Next, conversion from an abstract part into a concrete part in a graph in automated system design will be described. The example of FIG. 1 shows that graphs G2, G3 and G4 shown in FIG. 1 are derived by concretizing the graph G1 corresponding to the system requirement R1 based on a concretization rule to be described later. The graphs G2, G3 and G4 are system configuration proposals. A system configuration proposal includes an abstract component and is not a system requirement. As in the above, it is shown that a system concrete configuration G5 including no abstract element is derived by concretizing the system configuration proposal G2 using a concretization rule.

Further, although not illustrated in the example of FIG. 1, there may be a system configuration proposal derived by concretizing the graph G1 corresponding to the system requirement R1 other than the graphs G2, G3 and G4 of FIG. 1.

Next, a concretization rule will be described. A concretization rule is a rule for converting an abstract part included in a system requirement or a system configuration proposal into a concrete part. A concretization rule is information including detection information corresponding to an abstract part of a graph and conversion information corresponding to a concrete part of a graph.

Detection information and conversion information are graphs each including a node, an edge, or both, and one conversion information is associated with one detection information.

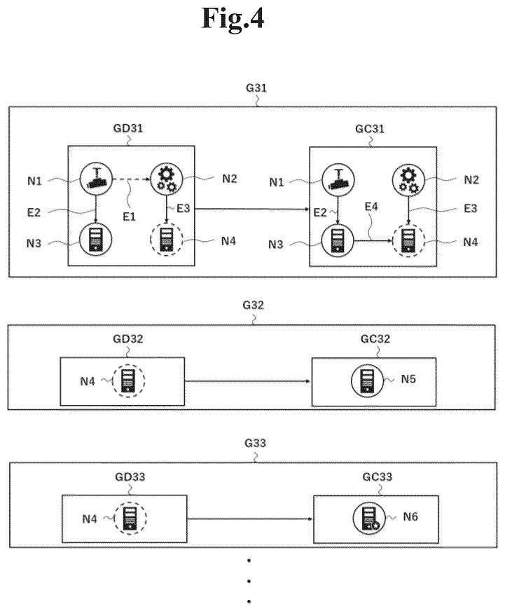

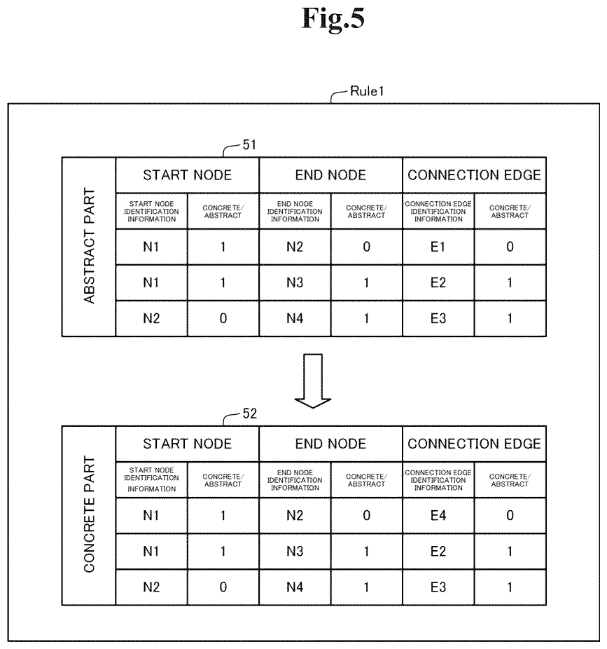

When the whole or part of a graph corresponding to a system requirement or a system configuration proposal matches the detection information included by a certain concretization rule, it is possible to concretize by applying the concretization rule and replacing the matching part with the conversion information. An example of the concretization rule will be described later with reference to FIG. 4. An example of the data structure of the concretization rule will be described later with reference to FIG. 5.

Although not illustrated in the example of FIG. 3, there are also system configuration proposals R2, R3 and R4 corresponding to the graphs G2, G3 and G4. Like the system requirement R1, each of the system configuration proposals R2, R3 and R4 is information including component identification information of all the nodes included in the configuration proposal, component identification information of all the edges, component identification information of the start nodes of the edges, and component identification information of the end nodes of the edges.

FIG. 4 is a view for explaining a concretization rule. FIG. 4 shows graphs G31, G32, G33, which are graphs representing a plurality of concretization rules.

The graph G31 is a graph representing a concretization rule Rule1 used for converting the graph G1 shown in FIG. 1 into the graph G2 shown in FIG. 1 (delete the edge E1, add an edge E4).

A graph GD 31 included by the graph G31 is a graph representing detection information, and a graph GC31 is a graph representing conversion information. Since the graph GD 31 matches the graph G1 shown in FIG. 1, the concretization rule Rule1 can be applied. Then, by applying the concretization rule Rule1, the configuration of the graph G1 is replaced with the configuration of the graph GC31 and becomes the graph G2.

Further, the graph G32 is a graph representing a concretization rule Rule2 used for converting the graph G1 shown in FIG. 1 into the graph G3 shown in FIG. 1 (convert the node N4 into a node N5). The graph G33 is a graph representing a concretization rule Rule3 used for converting the graph G1 shown in FIG. 1 into the graph G4 shown in FIG. 1 (convert the node N4 into a node N6). As in the graph G31, a graph GD32 included by the graph G32 is a graph representing detection information, and a graph GC32 is a graph representing conversion information. Since the graph GD 32 matches part of the graph G1 shown in FIG. 1, the concretization rule Rule2 can be applied. Then, by applying the concretization rule Rule2, part of the graph G1 (i.e., the node N4) is replaced with the graph GC32 (i.e., the node N5), and the graph G1 is thereby converted into the graph G3. Moreover, as in the graph G31, a graph GD33 included by the graph G33 is a graph representing detection information, and a graph GC33 is a graph representing conversion information. Since the graph GD 33 matches part of the graph G1 shown in FIG. 1, the concretization rule Rule3 can be applied. Then, by applying the concretization rule Rule3, part of the graph G1 (i.e., the node N4) is replaced with the graph GC33 (i.e., the node N6), and the graph G1 is thereby converted into the graph G4.

FIG. 5 is a view for explaining the data structure of a concretization rule. The concretization rule Rule1 shown in FIG. 5 is the concretization rule corresponding to the graph G31. The concretization rule Rule1 includes detection information 51 used for detecting an abstract part and conversion information 52 for converting the abstract part detected using the detection information 51 into a concrete part. Although not illustrated, there are the concretization rules Rule2, Rule3, . . . like that shown in FIG. 5 corresponding to the graphs G32, G33, . . . for the graphs G32, G33, . . . .

For deriving the graphs G2, G3 and G4 from the graph G1 shown in FIG. 1, first, the system requirement R1 is compared with a plurality of detection information (correspond to abstract part in concretization rule), and detection information that matches an abstract part included in the system requirement R1 is detected.

Next, using the detected detection information corresponding to the abstract part, the abstract part detected from the system requirement R1 is converted into conversion information (concrete part in concretization rule). The conversion into the graph G2 is done by replacement with the conversion information 52 of the concretization rule Rule1 because the system requirement R1 matches the detection information 51 of the concretization rule Rule1.

As a result, the edge E1 is deleted from the system requirement R1 and the edge E4 is added, and the system configuration proposal R2 corresponding to the graph G2 is generated, which is not illustrated. The system configuration proposals R3 and R4 corresponding to the graphs G3 and G4, respectively, are also generated.

Next, for each of the plurality of system configuration proposals having been generated, an abstract part in the system configuration proposal is converted into a concrete part using a concretization rule. Furthermore, in a case where a system configuration proposal with an abstract system configuration is generated, the abovementioned concretization process is repeated. Then, when no system configuration proposal is generated and only a system concrete configuration with no abstract part is left, the concretization process is stopped (automatic design is ended).

Here, when concretizing a system requirement and a system configuration proposal, a plurality of concretization rules are used, so that a system configuration proposal and a system concrete configuration to be derived vary in accordance with a selected concretization rule and the order of selection of concretization rules. That is to say, different system configuration proposals and system concrete configurations are derived in accordance with the type of the selected concretization rule.

Further, when the number of concretization rules to be applied increases, the number of system configuration proposals and system concrete configurations to be generated becomes enormous. Furthermore, the plurality of different system concrete configurations may include a system concrete configuration that does not satisfy a system requirement. Thus, as the number of concretization rules to be applied increases, it becomes difficult to efficiently derive a system concrete configuration.

Further, in order to efficiently derive a system concrete configuration, it is important to appropriately determine the quality of a concretization rule to be applied.

Then, a learning model is used to select a concretization rule to be applied. That is to say, evaluation is performed on system configuration proposals generated by execution of the concretization process, using a learning model acquired by machine learning, and a system configuration proposal with the highest evaluation value is selected from among the system configuration proposals. By thus repeating the concretization process using the learning model, the system concrete configuration can be derived efficiently.

Accordingly, in this example embodiment, a learning apparatus that generates a learning model for automatically designing a system as mentioned above is provided. Below, an automated system design learning apparatus in this example embodiment will be described with reference to the drawings. In the following drawings, elements having the same functions or corresponding functions are denoted by the same reference numerals, and repletion of description thereof may be omitted.

### [Configuration]

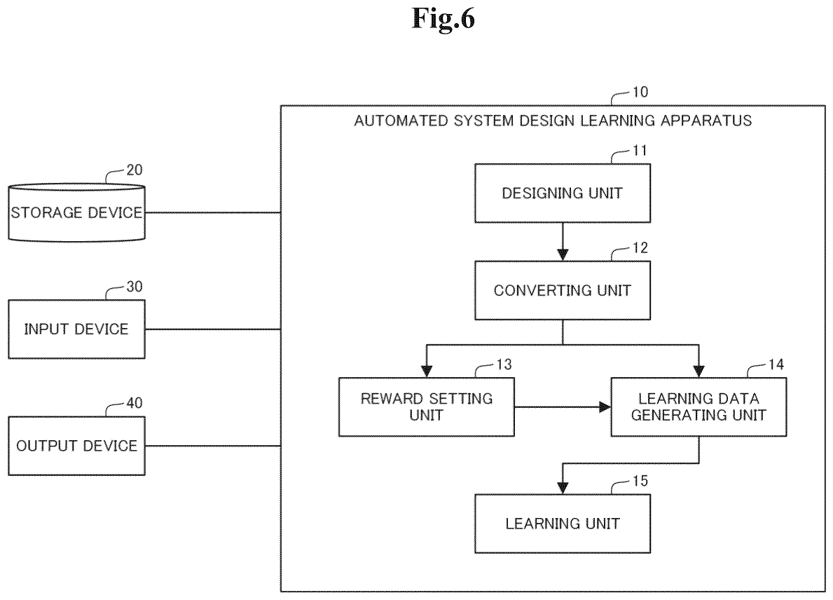

The configuration of an information processing system including an automated system design learning apparatus 10 in the first example embodiment will be described with reference to FIG. 6. FIG. 6 is a view showing an example of the information processing system.

As shown in FIG. 6, the information processing system includes an automated system design learning apparatus 10, a storage device 20, an input device 30, and an output device 40. The automated system design learning apparatus 10, the storage device 20, the input device 30, and the output device 40 are connected to be able to communicate via a network.

The automated system design learning apparatus 10 is an information processing apparatus such as a circuit, a server computer, a personal computer, or a mobile device equipped with a CPU (Central Processing Unit), a programmable device such as an FPGA (Field-Programmable Gate Array), a GPU (Graphics Processing Unit), or at least one or more of the above, for example.

The storage device 20 is a circuit or the like including a database, a server computer, and a memory. The storage device 20 stores a variety of information to be described later. In the example of FIG. 6, one storage device 20 is provided outside the automated system design learning apparatus 10, but a plurality of storage devices 20 may be provided inside or outside the automated system design learning apparatus 10.

The input device 30 is a device such as a keyboard, a mouse, or a touchscreen, for example. The input device 30 is used for operating the automated system design learning apparatus 10, the output device 40, and so forth. The output device 40 is a display device such as a display, for example.

The communication network is a general communication network constructed using communication lines, such as the Internet, a LAN (Local Area Network), a dedicated line, a telephone line, an in-house network, a mobile communication network, Bluetooth (registered trademark), and Wi-Fi (Wireless Fidelity), for example.

The automated system design learning apparatus 10 is an apparatus that learns a learning model for designing an ICT system. The automated system design learning apparatus 10 includes, as shown in FIG. 6, a designing unit 11, a converting unit 12, a reward setting unit 13, a learning data generating unit 14, and a learning unit 15. The respective functions of the designing unit 11, the converting unit 12, the reward setting unit 13, the learning data generating unit 14, and the learning unit 15 can be realized by execution of a program for realizing the respective functions stored in a storage device by an arithmetic logic unit such as the CPU provided in the information processing apparatus configuring the automated system design learning apparatus 10. Although the respective components will be described below, the overview of the respective components will be first described, and a detailed description will be made at the time of description of the operation later.

The designing unit 11 executes a concretization process of converting an abstract part (element) into a concrete part on a system requirement that is information showing a system configuration including an abstract part, generates a system concrete configuration that is information showing a system configuration including no abstract part, and generates design path information showing the process of generation from the system requirement to the system concrete configuration (information including a system requirement, a system configuration proposal in the process of deriving a system concrete configuration from the system requirement, and a system concrete configuration).

The converting unit 12 adds inheritance relation information of a component (element) to the design path information and thereby generates an inheritance relation embedded design path. Specifically, by converting type information showing the type of a component included in a system requirement, a system configuration proposal or a system concrete configuration included by the design path information into an inheritance relation embedded type to which type information of a type of a parent in the inheritance relation is added, based on type definition information for adding inheritance relation information to a type, the converting unit 12 generates an inheritance relation embedded system requirement, an inheritance relation embedded system configuration proposal, and an inheritance relation embedded system concrete configuration, and generates inheritance relation embedded design path information.

The reward setting unit 13 sets a reward for each of the inheritance relation embedded system requirement, the inheritance relation embedded system configuration proposal, and the inheritance relation embedded system concrete configuration included by the inheritance relation embedded design path information. The reward setting unit 13 also sets a reward for learning a system design method based on a function requirement.

The learning data generating unit 14 generates learning data in which a reward is associated with each of the inheritance relation embedded system requirement, the inheritance relation embedded system configuration proposal and the inheritance relation embedded system concrete configuration included by the inheritance elation embedded design path information.

The learning unit 15 learns a method for designing a system based on a function requirement on the basis of the learning data.

### [Operation]

Next, the operation of the automated system design learning apparatus 10 in the first example embodiment will be described. In the following description, the figures will be referred to as necessary. In the first example embodiment, an automated system design learning method is executed by causing the automated system design learning apparatus 10 to operate. Therefore, the description of the automated system design learning method in the first example embodiment is equal to the description of the operation of the automated system design learning apparatus below.

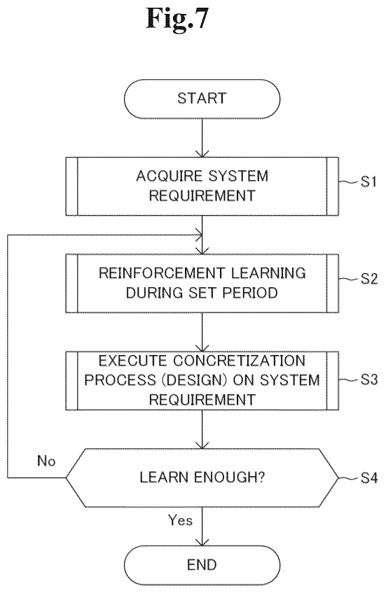

FIG. 7 is a view for explaining an example of the overall operation of the automated system design learning apparatus 10 in the first example embodiment. First, the automated system design learning apparatus 10 acquires a system requirement to be learned from the storage device 20 (step S1).

Next, the automated system design learning apparatus 10 executes reinforcement learning during a preset period using the system requirement to be learned (step S2). Consequently, a function requirement learning model is generated. For example, in a case where a neural network is used for reinforcement learning, a function requirement learning model refers to the neural network.

The preset learning period is determined by experiment, simulation, or the like, for example. The learning period may be the number of times of learning, instead of the learning period. For example, in the case of using a neural network, the number of times of learning is the number of updates of a weight of the neural network. However, the preset learning period is not limited to the learning period or the number of times of learning.

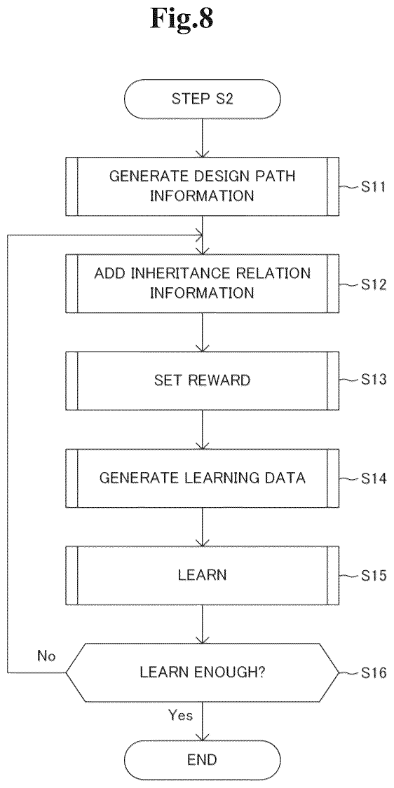

Here, the details of the operation in the function requirement learning that is the process at step S2 above will be described later with reference to FIG. 8. In the function requirement learning, a designing method related to a function requirement of the ICT system is learned.

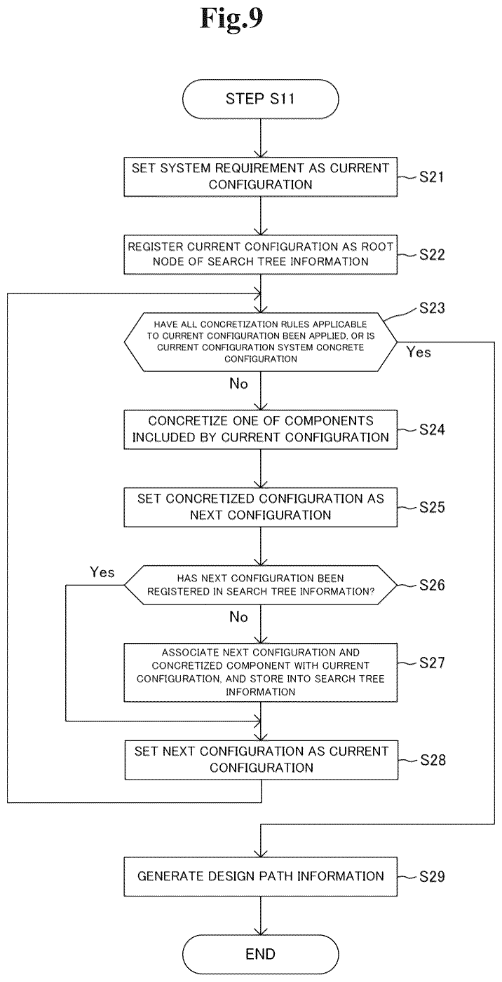

First, the designing unit 11 generates design path information using a system requirement (step S11). Specifically, the designing unit 11 generates design path information as shown in a flowchart of FIG. 9.

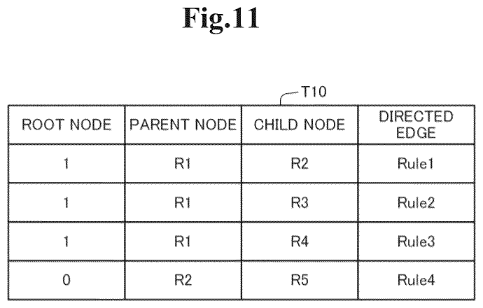

First, the designing unit 11 sets a system requirement to be a current configuration (step S21). Next, the designing unit 11 registers the current configuration as a root node of a search tree (step S22). Specifically, the designing unit 11 sets system requirement identification information for identifying the current configuration (system requirement) as a root node and stores it into search tree information. The data structure of the search tree information will be described later with reference to FIG. 11.

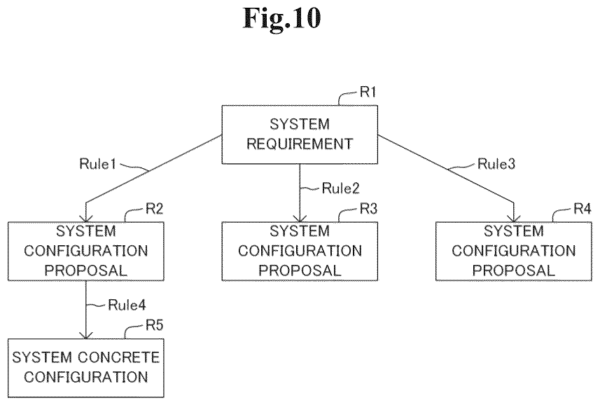

Here, FIG. 10 is a view for explaining an example of a search tree. A search tree can be represented by a graph (search tree T1) as shown in FIG. 10. The root node referred to in the above description of step S22 corresponds to the system requirement R1 in FIG. 10.

FIG. 11 is a view for describing an example of the data structure of the search tree information. The data structure shown in FIG. 11 corresponds to the search tree of FIG. 10. In the example of FIG. 11, system requirement identification information “R1” associated with the system requirement R1 stored in the storage device 20 is stored in “parent node” of the search tree information T10, and moreover, “1” is stored as information indicating that the system requirement R1 is “root node”.

Next, in a case where all concretization rules applicable to the current configuration have been applied, or in a case where the current configuration is a system concrete configuration (step S23: Yes), the designing unit 11 proceeds to a process at step S29.

Further, in a case where all concretization rules applicable to the current configuration have not been applied (No: step S23), the designing unit 11 repeats the processes from step S24 to step S28.

Next, the designing unit 24 concretizes one of the components included in the current configuration by executing a concretization process (step S24). Next, the designing unit 11 sets a configuration obtained by concretizing the abovementioned component at step S23 as a next configuration (step S25).

Next, in a case where the next configuration (concretized configuration (system configuration proposal)) is not stored in the search tree information (step S26: No), the designing unit 11 proceeds to a process of step S27. In a case where the next configuration (concretized configuration (system configuration proposal)) is stored in the search tree information (step S26: Yes), the designing unit 11 proceeds to a process of step S28.

Next, with a node representing the current configuration as a parent node, the next configuration (concretized configuration) as a child node, and an edge representing the concretized component (concretized component of concretization rule) as a directed edge, the designing unit 11 associates the next configuration and the concretized component with current configuration and stores into the search tree information (step S27).

For example, in a case where the current configuration is the system requirement R1 and the system configuration proposal R2 is generated from the system requirement R1, system configuration proposal identification information “R1” corresponding to the system requirement R1 in the search tree information T10, system configuration proposal identification information “R2” corresponding to the system configuration proposal R2 generated through the concretization process, and concretization identification information “Rule1” corresponding to the concretization rule used in the concretization process are associated and stored as shown in FIG. 11.

Further, in a case where the current configuration is the system configuration proposal R2 and a concrete configuration R5 is generated from the system requirement proposal R2, the system configuration proposal identification information “R2” of the search tree information T10, the system configuration proposal identification information “R5” associated with the concrete configuration generated through the concretization process, and the concretization rule identification information “Rule4” associated with the concretization rule used in the concretization process are associated and stored as shown in FIG. 11.

Next, the designing unit 11 sets the next configuration as a current configuration (step S28).

Next, the designing unit 11 generates a series of paths (design path information that stores configurations in chronological order) until the current system concrete configuration is generated from the system requirement, based on the system configurations (system requirement, system configuration proposal, system concrete configuration) obtained through the processes from steps S21 to S28 described above (step S29). The designing unit 11 also generates a series of paths in a case where the system concrete configuration is not generated from the system requirement, that is, a series of paths until the system configuration proposal is generated from the system requirement.

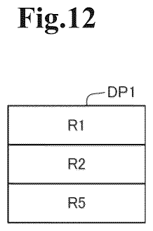

FIG. 12 is a view for explaining an example of the data structure of the design path information. In design path information DP1 shown in FIG. 12, the system requirement “R1”, the system configuration proposal “R2”, and the system concrete configuration “R5” shown in FIGS. 10 and 12 are recorded in this order. That is to say, the design path information DP1 shows that, as one of the processes in system design, there is a series of design processes starting from the system requirement “R1”, passing through the system configuration proposal “R2”, and leading to the system concrete configuration “R5”.

The information included by the design path information (information corresponding to “R1”, “R2”, “R5” in the example of FIG. 12) are simply symbols associated with a system requirement, a configuration proposal, or a concrete configuration. That is to say, since the design path information is merely a string of symbols, information about elements configuring a system requirement, a configuration proposal, or a concrete configuration (information about nodes and edges) is not stored.

As will be described later, the design path information is information that is first replaced with inheritance relation embedded design path information indicating an inheritance relation embedded configuration with inheritance relation information embedded in each of the associated configurations (configurations such as R1, R2 and R5) and is then used for generating learning data.

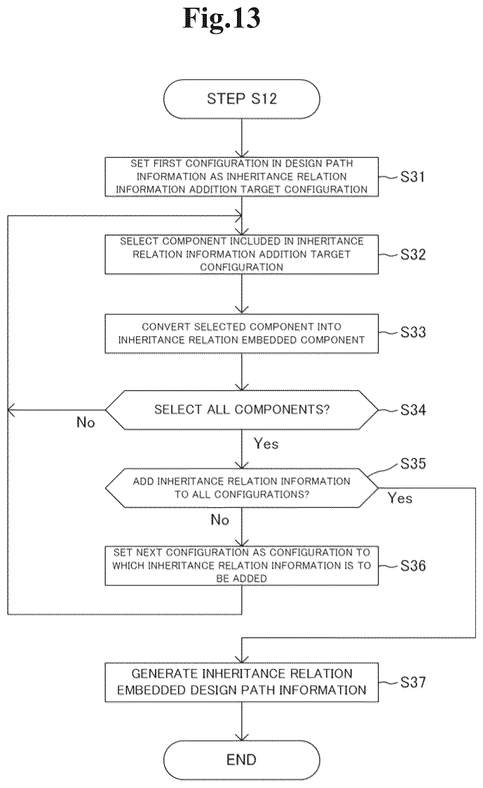

After generating the design path information in the above manner (step S11 in FIG. 8), the converting unit 12 converts each of the system configurations in the design path (information including the abovementioned system requirement or system configuration proposal or system concrete configuration) (system configuration information) into an inheritance relation embedded system configuration with inheritance relation information added to, and generates an inheritance relation embedded design path (embedded design path information) (step S12 in FIG. 8). Specifically, the converting unit 12 generates an inheritance relation embedded design path as shown in a flowchart of FIG. 13. The process of generating an inheritance relation embedded design path by the converting unit 12, which will be described below, is performed for each path, which is a series of design processes.

First, the converting unit 12 sets the first configuration in the design path information as an inheritance relation information addition target configuration (step S31). Next, the converting unit 12 selects one component from among components included in the inheritance relation addition target configuration (step S32).

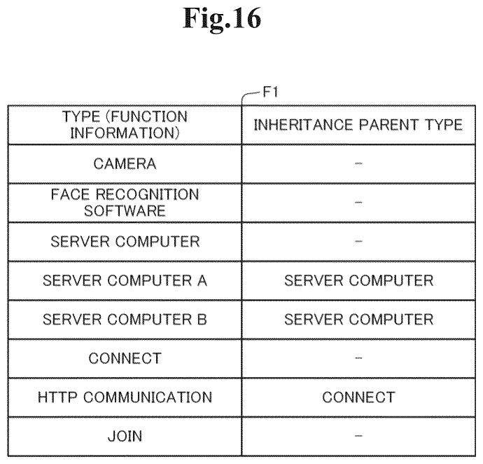

Next, the converting unit 12 converts the selected component into an inheritance relation embedded component (step S33). The details of step S33 will be described later with reference to FIG. 16.

Next, in a case where there is no selectable component, that is, in a case where all the components have been selected (step S34: Yes), the converting unit 12 proceeds to a process of step S35. In a case where there is a selectable component (step S34: No), the converting unit 12 proceeds to the process of step S32, and repeats the processes of steps S32 to S33 until there is no unselected component.

Next, in a case where inheritance relation information has not been added to all the system configurations included in the design path information (in a case where adding inheritance relation information has not been finished to the last configuration in the design path information) (step S35: No), the converting unit 12 sets the next configuration included in the design path information as the target for adding inheritance relation information (step S36). After executing step S36, the converting unit 12 proceeds to the process of step S32.

Further, at step S35, in a case where inheritance relation information has been added to all the system configurations included in the design path information (in a case where adding inheritance relation information has been finished to the last configuration in the design path information) (step S35: Yes), the converting unit 12 proceeds to a process of step S37. That is to say, the converting unit 12 stores in chronological order the inheritance relation embedded system requirement, the inheritance relation embedded system configuration proposal and the inheritance relation embedded system concrete configuration generated through the inheritance relation information adding process of steps S31 to S36, and generates inheritance relation embedded design path information from these inheritance relation embedded system configurations.

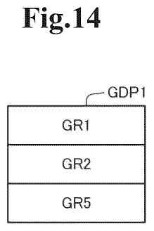

FIG. 14 is a view for describing an example of the data structure of the inheritance relation embedded design path information. Inheritance relation embedded design path information GDP1 shown in FIG. 14 represents a configuration in which inheritance relation information is embedded in the components of the respective configurations associated with those of the design path information DP1 shown in FIG. 12. That is to say, an inheritance relation embedded system requirement “GR1”, an inheritance relation embedded system configuration proposal “GR2” and an inheritance relation embedded system concrete configuration “GR5” shown in FIG. 14 refer to the system requirement “R1”, system configuration proposal “R2” and system concrete configuration “R5” in which inheritance relation information have been added to the components.

Just as the information included by the design path information are merely symbols associated with the system requirement, the system configuration proposal and the system concrete configuration, the information included by the inheritance relation embedded design path information are merely symbols associated with the inheritance relation embedded system requirement, the inheritance relation embedded system configuration proposal, and the inheritance relation embedded system concrete configuration. Moreover, the inheritance relation embedded design path information is information used for generating learning data, as will be described later.

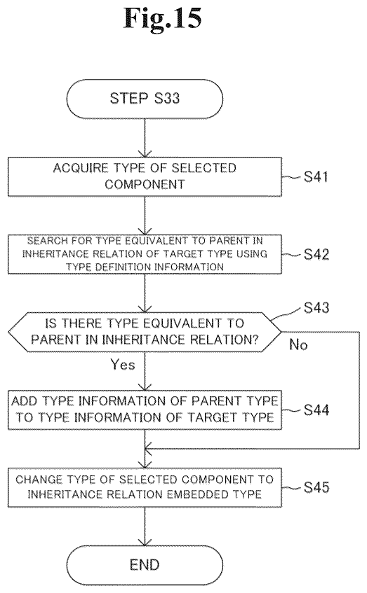

Here, the process of step S33 in FIG. 13 described above, that is, the process of converting the component included by the configuration in the design path information into an inheritance relation embedded component will be described with reference to a flowchart of FIG. 15.

First, the converting unit 12 acquires the type of the component selected at step S32 shown in FIG. 13, and sets it as a target component type (step S41). Specifically, the converting unit 12 acquires the type of the selected component with reference to the component information. For example, the converting unit 12 may acquire function information corresponding to the selected component with reference to the component information. Moreover, type information representing a type may be stored in association with the component identification information included by the component information, and type information corresponding to the selected component may be acquired. The method for acquiring the type of the selected component may be a method other than the above one.

Next, the converting unit 12 searches for a type equivalent to a parent in the inheritance relation of the target type, using type definition information (step S42). The type definition information is information in which type information representing a type is associated with inheritance parent type information for adding type information of a type equivalent to a parent in the inheritance relation to the type information. The type definition information is stored in the storage device 20 or the like.

Here, the type information is information representing the function, product name and so forth of a component, for example. The inheritance parent type information is information representing the function and product name of a component as a superordinate concept and expressing in an abstract manner. A specific description will be given with reference to FIG. 16.

FIG. 16 is a view for describing the data structure of the type definition information. This view shows type definition information used in designing the face recognition system shown in FIG. 1. In the example of type definition information F1 shown in FIG. 16, the names of types such as “camera”, “face recognition software”, “server computer”, “server computer A”, “server computer B”, “connect”, “HTTP communication”, and “join” are stored as “type (function information)” representing types. Moreover, in FIG. 16, type information of a type equivalent to the parent of “type” is stored as “inheritance parent type” representing an inheritance parent type.

In the example of FIG. 16, for type “camera”, there is no type defined as the parent of camera, so that “-” indicating that there is no “inheritance parent type” is stored. Since “server computer A” is included by category “server computer”, “server computer” is stored in “inheritance parent type”.

In the example of FIG. 16, the types used in the description of the face recognition system of FIG. 1 are shown as examples of the stored types, but the types stored in the type definition information are not limited to the types described in FIG. 16. Types other than the types described in FIG. 16 can be defined, and inheritance parent types corresponding to the respective types can be defined. Moreover, in the type definition information shown in FIG. 16, only “type” and “inheritance parent type” are defined, but other information may be stored. For example, information such as whether the type is abstract or not and an attribute value related to the performance of a component associated with the type may be associated.

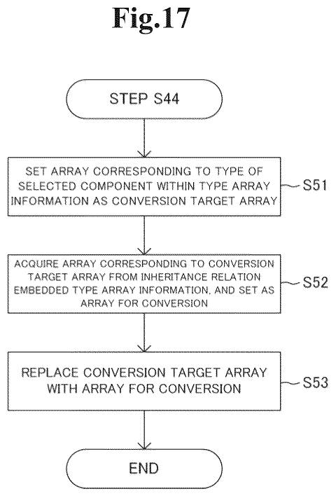

Next, the converting unit 12 refers to the type definition information and, in a case where there is a type equivalent to a parent in the inheritance relation of the target type, namely, a superordinate concept (step S43: Yes), adds the type information of the parent to the type information of the target type (step S44), and proceeds to a process of step S45. A method for adding the type information of the parent to the target type will be described later with reference to FIG. 17.

Further, the converting unit 12 refers to the type definition information and, in a case where there is no type equivalent to a parent in the inheritance relation of the target type (step S43: No), proceeds to the process of step S45.

Then, the converting unit 12 changes the type of the selected component to an inheritance relation embedded type. That is to say, the converting unit 12 changes the type (function information and so forth) of the component information to an inheritance relation embedded type (step S45).

Next, the process to add the type information of the inheritance parent to the type at step S44 in FIG. 15 mentioned above will be described with reference to a flowchart of FIG. 17.

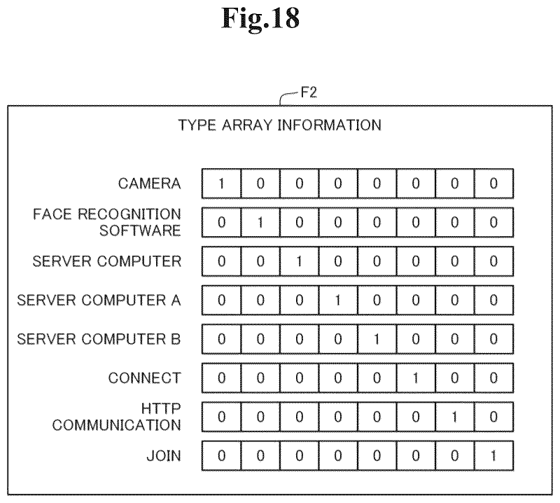

First, the converting unit 12 sets an array corresponding to the type of the selected component in type array information as a conversion target array (step S51). FIG. 18 shows an example of the data structure of the type array information. Reference symbol F2 in FIG. 18 denotes an example of the data structure of type array information corresponding to the type definition information F1 shown in FIG. 16. Type array information is information that associates the types stored in the type definition information with arrays each having elements of “0” and “1”. Such a data structure is generally called a one-hot vector. The size of each array included by the type array information is equal to the number of types stored in the type definition information. Moreover, the elements of the array correspond to the types stored in the type definition information in the order that they are defined.

For example, for the first defined type “camera” in the type definition information, an array corresponding to “camera” in the type array information F2 (an array “camera”) stores “1” in the first element and “0” in the remaining elements. Also, for each of the types other than “camera”, an array that stores “1” in a position corresponding to the type and “0” in the other positions is stored.

Next, the converting unit 12 acquires an array corresponding to the conversion target array from inheritance relation embedded type array information, and sets the array as an array for conversion (step S52). Then, the converting unit 12 replaces the conversion target array with the array for conversion (step S53).

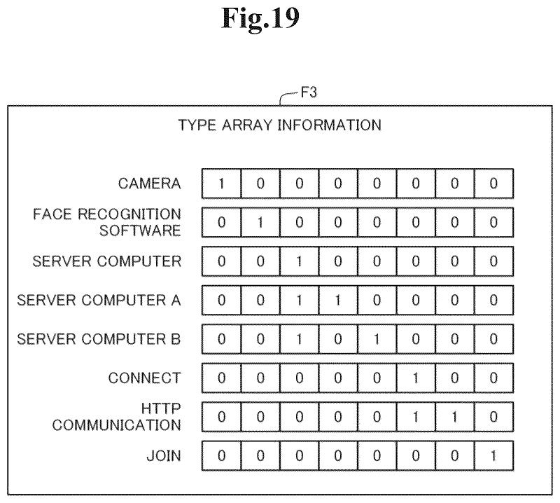

FIG. 19 shows an example of the data structure of inheritance relation embedded type array information F3. The inheritance relation embedded type array information F3 is information in which information of inheritance relations are added to all the arrays included in the type array information F2 of FIG. 18 and these arrays are compiled.

For example, in the case of an array “server computer A” in the inheritance relation embedded type array information F3, referring to the type definition information F1 in FIG. 16, the inheritance parent type is “server computer”. Since the type “server computer” is defined third in the type definition information, the third element of the array “server computer A” (an element at a position corresponding to server computer) is converted to “1”. At this time, “1” is also stored in the fourth element of the array “server computer A”. This is because, according to the type definition information F1 in FIG. 16, the server computer A is defined fourth. That is to say, the element in the position corresponding to “server computer A” itself (fourth position) and the element in the position corresponding to its parent type “server computer” (third position) are both set to “1”.

Similarly, for each of the remaining types, “1” is stored in an element corresponding to the type itself and, in a case where a type equivalent to its parent is defined, “1” is stored in an element corresponding to the type of the parent.

The example of FIG. 19 shows arrays to which information on the types of parents in the inheritance relation are added, but information to be added do not have to be limited to information on the types of parents. That is to say, for example, information on a type equivalent to the parent of the parent may be added.

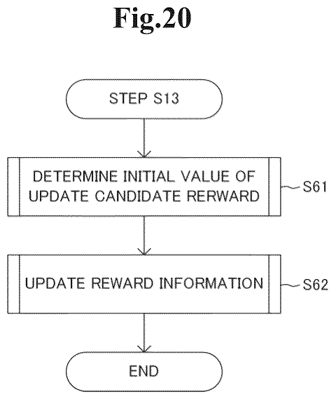

After the inheritance relation embedded design path information is generated in the manner described above (step S12 in FIG. 8), a reward is set for each of the inheritance relation embedded system configurations (the inheritance relation embedded system requirement, the inheritance relation embedded system configuration proposal, or the inheritance relation embedded system concrete configuration described above) in the inheritance relation embedded design path information (step S13 in FIG. 8). Specifically, the reward setting unit 13 sets a reward as shown in the flowchart of FIG. 20. The reward setting process by the reward setting unit 13 described below is performed for each path, which is a series of design processes.

Here, in system design described in the present disclosure, it is important to apply an appropriate concretization rule to a configuration proposal and reach a system concrete configuration with efficiency. Then, a process to give the probability that each configuration proposal can reach a concrete configuration as a reward using the inheritance relation embedded design path information.

First, the reward setting unit 13 determines the initial value of an update candidate reward (step S61). Specifically, in a case where the last configuration in the inheritance relation embedded design path is an inheritance relation embedded system concrete configuration, the reward setting unit 13 sets, for example, reward information representing a reward for the inheritance relation embedded system concrete configuration to “1” as the initial value of the update candidate reward and, in a case where not the inheritance relation embedded system concrete configuration, the reward setting unit 13 sets, for example, reward information representing a reward corresponding to the last configuration to “0”.

Here, the abovementioned update candidate reward is a value used when updating the value of a reward that each of the system configurations (inheritance relation embedded system configurations) in the inheritance relation embedded design path information can obtain at step S62 described later.

In the example shown in FIG. 14, the last configuration in the inheritance relation embedded design path information GDP1 is the inheritance relation embedded system concrete configuration GR5, so that the reward information “1” is associated with “GR5” representing the inheritance relation embedded system concrete configuration in the inheritance relation embedded design path information GDP1 in the process at step S61.

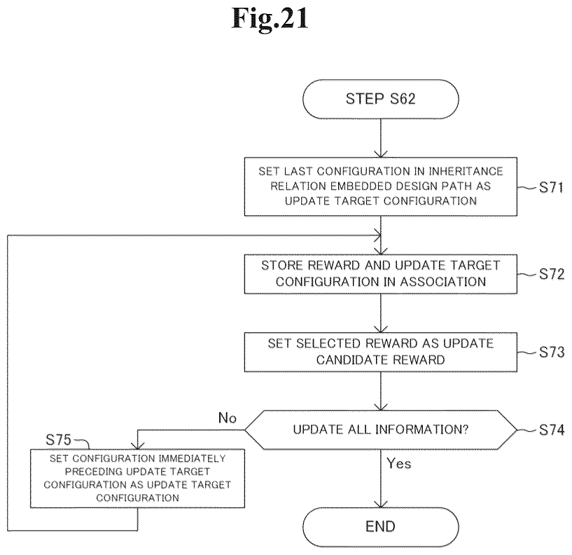

Next, the reward setting unit 13 updates the reward information of each of the system configurations (inheritance relation embedded system configurations) included in the inheritance relation embedded design path information (step S62). Specifically, the reward setting unit 13 performs a process to update the reward information as shown in a flowchart of FIG. 21.

First, the reward setting unit 13 sets the last configuration (inheritance relation embedded system configuration) in the inheritance relation embedded design path information as an update target configuration (step S71). Next, the reward setting unit 13 compares a reward associated with the update target configuration with the update candidate reward, selects the larger reward, and stores the selected reward in association with the update target configuration (step S72). Next, the reward setting unit 13 sets the reward selected at step S72 (the larger reward in comparison) as the update candidate reward (step S73).

Next, in a case where the reward update process has not been performed on all the configurations in the inheritance relation embedded design path information (in a case where execution of the reward update process has not finished to the first configuration in the inheritance relation embedded design path information) (step S74: No), the reward setting unit 13 sets a configuration immediately preceding the current update target configuration as an update target configuration (step S75), and proceeds to the process of step S72.

Further, in a case where the reward update process has been executed on all the configurations in the inheritance relation embedded design path information (in a case where the reward update process has finished to the first configuration in the inheritance relation embedded design path information) (step S74: Yes), the reward setting unit 13 ends the process of step S62 shown in FIG. 20.

Specifically, after comparison between the reward associated with the update target configuration and the update candidate reward, the reward setting unit 13 considers the update candidate reward to be “0” if any reward has not been associated with the update target configuration yet before the comparison. Then, after the comparison, updates with the larger one as the reward associated with the update target configuration and the update candidate reward. After that, the reward setting unit 13 updates the update target configuration, and repeats these processes.

For example, a reward is not associated with any of the configurations at first, so that in the example of FIG. 14, “GR5” is the first update target configuration at step S71. Since a reward has not been associated with “GR5” yet, its value is considered to be “0”. In that case, the update candidate reward has been initialized to “1” at step S61, so that “0” and “1” are compared with each other, and the larger reward “1” is associated with “GR5”.

Next, “GR2” is set as the update target configuration, and the same process as the abovementioned process is repeated. After that, further, “GR1” is set as the update target configuration, and the same process as the abovementioned process is repeated.

As another example, starting as the first update target configuration (a configuration that is not an inheritance relation embedded system concrete configuration), in a case where it is not a concrete configuration, the update candidate reward is initialized to “0”. In a case where a reward “1” is associated with the next configuration, “0” and “1” are compared. Since “1” is greater, the value of the update candidate reward is updated to “1”.

Specifically, in the process of step S62, data (reward) for learning the evaluation values of the configurations “GR2” and “GR1” in the design process based on the evaluation value of the configuration “GR5” at the end of the design is generated from the process performed at step S71. At this time, if larger data (reward) has been obtained in the past, it is given priority, so that the larger reward is compared with the reward stored in association with the configuration, and the larger one is left.

In the above description, the larger one is left and propagated upward (“GR1” when seen from “GR2”) because it is known that a transition can be made from “GR1” to “GR2”. What is wanted to learn is an expected reward to be obtained when the best option is kept to be selected, and it is known that a transition can be made from “GR1” to “GR2” when an appropriate concretization rule is applied, so that if the reward associated with “GR2” is greater, the reward for “GR5” should be propagated to “GR1” as a priority.

A transition from “GR1” to “GR2” does not necessarily occur, but there is a possibility thereof. For example, in the example of FIG. 10, there is a possibility of transition to “GR3” or “GR4”. However, the automatic design function can select which transition to make, so that a larger reward in comparison is propagated upward.

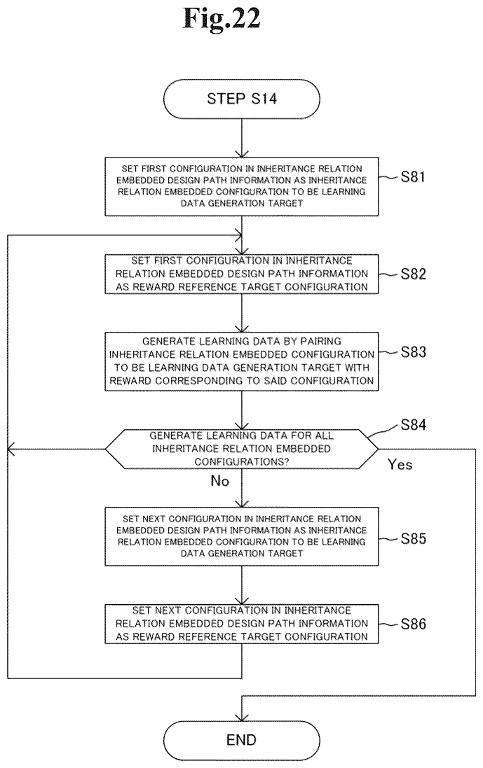

After setting the reward in the above manner (step S13 in FIG. 8), the learning data generating unit 14 generates learning data by associating the inheritance relation embedded design system configuration with the reward for the inheritance relation embedded design path information, and stores the generated learning data into the storage device 20 (step S14 in FIG. 8). Specifically, the learning data generating unit 14 generates learning data as shown in a flowchart of FIG. 22.

First, the learning data generating unit 14 sets the first configuration in the inheritance relation embedded design path information as an inheritance relation embedded configuration to be a learning data generation target (step S81). Next, the learning data generating unit 14 sets the first configuration in the inheritance relation embedded design path information as a reward reference target configuration (step S82).

Next, the learning data generating unit 14 generates learning data by pairing the inheritance relation embedded configuration to be the learning data generation target with a reward corresponding to that configuration (the reward set at step 72 of FIG. 21), and stores the generated learning data into the storage device 20 (step S83).

Next, in the case of having not generated learning data for all the configurations included in the inheritance relation embedded design path information (in the case of having not finished generating learning data to the last configuration in the inheritance relation embedded design path information) (step S84: No), the learning data generating unit 14 proceeds to a process at step S85. In the case of having generated learning data for all the configurations included in the inheritance relation embedded design path information (in the case of having finished generating learning data to the last configuration in the inheritance relation embedded design path information) (step S84: Yes), the learning data generating unit 14 ends the process to generate learning data.

Next, the learning data generating unit 14 sets the next configuration in the inheritance relation embedded design path information as a learning data generation target configuration (step S85).

Next, the learning data generating unit 14 sets the next configuration in the inheritance relation embedded design path information as a reward reference target configuration (step S86).

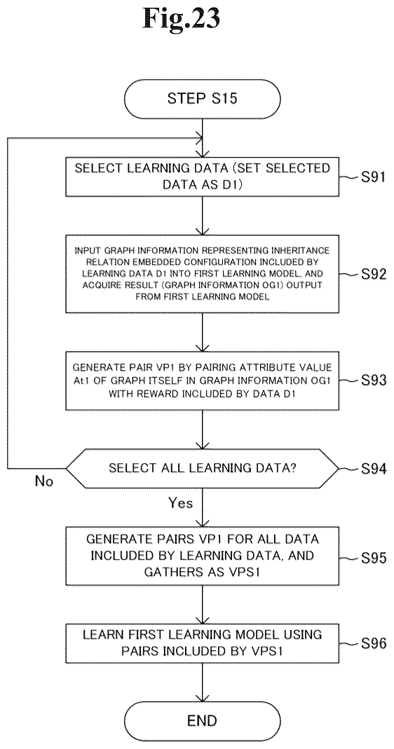

After the learning data is generated in the above manner (step S14 of FIG. 8), the learning unit 15 performs learning based on the learning data (step S15 of FIG. 8). Specifically, the learning unit 15 performs learning of a learning model as shown in a flowchart of FIG. 23.

Here, a learning model to be learned is a GNN (Graph Neural Network) that receives graph information in which each node and edge in a graph and the graph itself have attribute values as input and outputs graph information in the same format. It is assumed that the attribute value of each node or edge in the graph or the graph itself includes at least the inheritance relation embedded type array information described above as part thereof.

First, the learning unit 15 selects one learning data D1 from the learning data generated as described above (step S91). Next, the learning unit 15 inputs graph information representing an inheritance relation embedded configuration included by the learning data D1 into a first learning model, and acquires a result (graph information OG1) output from the learning model (step S92).

Next, the learning unit 15 generates a pair VP1 by pairing an attribute value At1 of the graph itself of the graph OG1 with a reward included in the data D1 (step S93).

Next, in the case of having selected all the learning data (step S94: Yes), the learning unit 15 proceeds to a process at step S95. In the case of having not selected all the learning data (step S94: No), the learning unit 15 proceeds to the process at step S91, and executes the processes up to step S93 again.

Next, the learning unit 15 generates pairs VP1 for all the data included in the learning data and gathers as VPS1 (step S95).

Then, the learning unit 15 learns the first learning model using the respective pairs included in VPS1 (step S96). Specifically, the learning unit 15 uses the respective pairs included in VPS1 to learn the learning model so as to minimize a loss function, which is the mean square error between the attribute value and a determined reward.

As described above, during a preset learning period, the processes from step S11 to step S15 shown in FIG. 8 are repeated (step S16 in FIG. 8) to perform reinforcement learning (step S2 in FIG. 7).

Then, using the learning model of the function requirement at the current moment generated through the abovementioned reinforcement learning, the automated system design learning apparatus 10 execute a concretization process (design) on the system requirement (step S3 of FIG. 7).

The concretization process (design) is a process to concretize an abstract part (component) included in a system requirement. By repeatedly executing the concretization process, it is possible to finally derive a system concrete configuration including only a concrete part. An example of the concretization process is as shown in FIG. 1.

Subsequently, in a case where it is determined that learning of a function requirement is enough based on the result of step S3 (step S4: Yes), the automated system design learning apparatus 10 ends reinforcement learning at step S2. In a case where it is determined that learning of a function requirement is not enough (step S4: No), the automated system design learning apparatus 10 repeats the processes of steps S2 and S3 until it is determined that learning of a function requirement is enough.

In the determination at step S4, it is determined to be enough, for example, when the number of steps of search is equal to or less than a preset threshold value A. Also, in the determination at step S4, it may be determined to be enough when the number of steps of search performed at step S3 in the past is equal to or less than a preset threshold value B consecutively for a specified number of times. However, the determination at step S4 is not limited to the abovementioned methods.

The number of steps in search described above depends on the method for design at step S3. The number of steps in search is the number of times that concretization rules are applied to a system requirement or a system configuration proposal until a system concrete configuration is derived from the system requirement. The number of steps in search can also be expressed as the number of system configuration proposals actually reached during the design.

As described above, according to this example embodiment, it is possible to reduce the time cost for relearning that is required when an element is added in automated system design.

Further, by generating learning data using data provided with information on a type equivalent to a parent in the inheritance relation, and learning using the learning data, it is possible to utilize, for evaluation of a type, the learning experience of a type in the inheritance relation with the type. Therefore, it is possible to increase the precision of evaluation of a configuration including a component having a type (an unlearned type) that does not exist in the past learning data. Consequently, when newly adding elements (components, relation between components) to be used in the system design, there is no need to relearn the system design using those elements, thereby reducing the time cost required for relearning.

### Second Example Embodiment

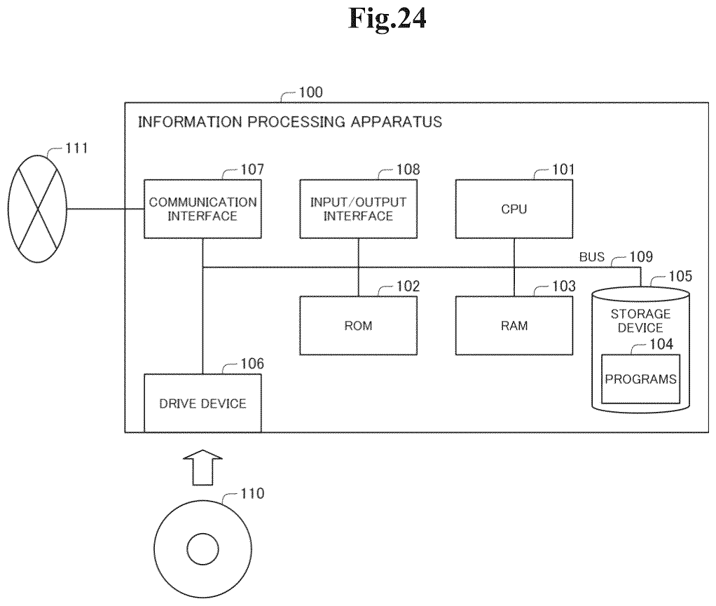

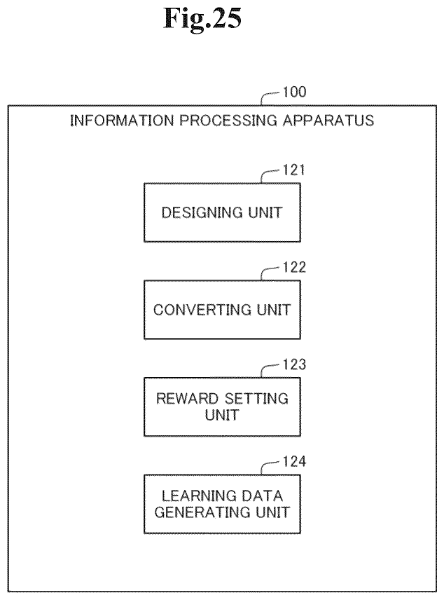

Next, a second example embodiment of the present disclosure will be described with reference to the drawings. In this example embodiment, the overview of the configuration of the automated system design learning apparatus described in the above example embodiment will be shown. FIGS. 24 to 25 are views for explaining the configuration, and these drawings may be relevant to any of the example embodiments.

First, the hardware configuration of an information processing apparatus 100 will be described with reference to FIG. 24. The information processing apparatus 100 is configured with a general information processing apparatus and, as an example, has the following hardware configuration including;
a CPU (Central Processing Unit) 101 (arithmetic logic unit),
a ROM (Read Only Memory) 102 (memory unit),
a RAM (Random Access Memory) 103 (memory unit),
programs 104 loaded to the RAM 103,
a storage device 105 storing the programs 104,
a drive device 106 performing reading from and writing into a storage medium 110 outside the information processing apparatus,
a communication interface 107 connected to a communication network 111 outside the information processing apparatus,
an input/output interface 108 inputting and outputting data, and
a bus 109 connecting the respective components.

FIG. 24 shows an example of the hardware configuration of the information processing apparatus serving as the information processing apparatus 100, and the hardware configuration of the information processing apparatus is not limited to the abovementioned case. The information processing apparatus may be configured with part of the above configuration, for example, may omit the drive device 106. Moreover, the information processing apparatus can use, instead of the abovementioned CPU, a GPU (Graphic Processing Unit), a DSP (Digital Signal Processor), an MPU (Micro Processing Unit), an FPU (Floating point number Processing Unit), a PPU (Physics Processing Unit), a TPU (Tensor Processing Unit), a quantum processor, a microcontroller, a combination thereof, or the like.

Then, by causing the CPU 101 to acquire and execute the programs 104, the information processing apparatus 100 can construct and include a designing unit 121, a converting unit 122, a reward setting unit 123, and a learning data generating unit 124 shown in FIG. 25. The programs 104 are, for example, stored in advance in the storage device 105 or the ROM 102, and are loaded to the RAM 103 and executed by the CPU 101 as required. The programs 104 may be provided to the CPU 101 via the communication network 111, or may be stored in advance in the storage medium 110 and be read out by the drive device 106 and provided to the CPU 101. However, the designing unit 121, the converting unit 122, the reward setting unit 123, and the learning data generating unit 124 mentioned above may be constructed using dedicated electronic circuits for realizing such means.

The designing unit 121 generates, for system configuration information representing a system configuration including a combination of elements, design path information representing a design process of the system configuration information designed by converting an abstract element into a concrete element using a preset concretization rule.

The converting unit 122 generates embedded design path information in which to each of the system configuration information included in the design path information, information of an element corresponding to a superordinate concept of the element included in the system configuration information is added.

The reward setting unit 123 sets, for each of the system configuration information included in the embedded design path information, a reward for the system configuration information in accordance with whether or not the element included in the system configuration information is a concrete element.

The learning data generating unit 124 generates each of the system configuration information included in the embedded design path information and the reward set for the system configuration information as learning data to be machine-learned for generating a model that converts the system configuration information based on the concretization rule.

With the configuration as described above, the present disclosure can reduce time cost for system design.

At least one or more of the functions of the designing unit 121, the converting unit 122, the reward setting unit 123, and the learning data generating unit 124 described above may be executed by an information processing apparatus installed and connected at any place on the network, that is, may be executed by so-called cloud computing.

Further, the abovementioned programs can be stored using various types of non-transitory computer-readable mediums and provided to a computer. The non-transitory computer-readable mediums include various types of tangible storage mediums. Examples of the non-transitory computer-readable mediums include a magnetic recording medium (e.g., floppy disk, magnetic tape, hard disk drive), a magneto-optical recording medium (e.g., magneto-optical disk), a CD-ROM (Read Only Memory), a CD-R, a CD-R/W, and a semiconductor memory (e.g., mask ROM, PROM (Programmable ROM), EPROM (Erasable PROM), flash ROM, and RAM (Random Access Memory)). The programs may also be provided to a computer by various types of transitory computer-readable mediums. Examples of the transitory computer-readable mediums include an electric signal, an optical signal, and an electromagnetic wave. The temporary computer-readable medium can provide the program to a computer via a wired communication path such as an electric wire or an optical fiber, or via a wireless communication path.

Although the present disclosure has been described above with reference to the example embodiments and so forth, the present disclosure is not limited to the above example embodiments. The configuration and details of the present disclosure can be changed in various manners that can be understood by one skilled in the art within the scope of the present disclosure. The above example embodiments can be combined with another example embodiment as required.

### Supplementary Notes

The whole or part of the example embodiments disclosed above can be described as in the supplementary notes. Below, the overview of the configurations of the information processing apparatus, the information processing method, and the program in the present disclosure will be described. However, the present disclosure is not limited to the following configurations.

### (Supplementary Note 1)

An information processing apparatus comprising:
a designing unit that generates, for system configuration information each representing a system configuration including a combination of elements, design path information representing a design process of the system configuration information designed by converting an abstract element into a concrete element using a preset concretization rule;
a converting unit that generates embedded design path information in which each system configuration information of the system configuration information included in the design path information is provided with information of an element corresponding to a superordinate concept of the element included by each system configuration information;
a reward setting unit that sets, for each system configuration information of the system configuration information included in the embedded design path information, a reward for each system configuration information in accordance with whether or not the element included by each system configuration information is a concrete element; and
a learning data generating unit that, by using each system configuration information of the system configuration information included in the embedded design path information and the reward set for each system configuration information, generates learning data to be machine-learned for generating a model that converts the system configuration information based on the concretization rule.

### (Supplementary Note 2)

The information processing apparatus according to Supplementary Note 1, wherein
the converting unit generates, for each system configuration information of the system configuration information included in the design path information, the embedded design path information including information on the element included by each system configuration information and on an element corresponding to a superordinate concept of the element, based on inheritance relation information representing an element corresponding to a superordinate concept of an element.

### (Supplementary Note 3)

The information processing apparatus according to Supplementary Note 2, wherein
the converting unit shows, for each system configuration information of the system configuration information included in the design path information, presence or absence of the elements in each system configuration information using an array, and generates the embedded design path information by providing the array of the elements included by each system configuration information with information of elements corresponding to superordinate concepts of the elements.

### (Supplementary Note 4)

The information processing apparatus according to Supplementary Note 1, wherein:
the converting unit generates the embedded design path information for each path representing a series of design processes of the system configuration information based on the design path information; and
the reward setting unit sets, for each path, the reward for each system configuration information of the system configuration information included in the embedded design path information.

### (Supplementary Note 5)

The information processing apparatus according to Supplementary Note 4, wherein
in the same path, the reward setting unit sets the reward for the system configuration information in a predetermined process included in the embedded design path information and, based on the reward, sets the reward for the other system configuration information.

### (Supplementary Note 6)

The information processing apparatus according to Supplementary Note 5, wherein
in the same path, the reward setting unit sets the reward for the system configuration information in a last process included in the embedded design path information and, based on the reward, sets the reward for the other system configuration information.

### (Supplementary Note 7)

The information processing apparatus according to Supplementary Note 5, wherein
in the same path, the reward setting unit sets the largest reward set for the system configuration information in a predetermined process included in the embedded design path information, as the reward for the other system configuration information.

### (Supplementary Note 8)

The information processing apparatus according to Supplementary Note 1, comprising
a learning unit that, by using a loss based on the reward, generates the model that converts each system configuration information of the system configuration information included in the embedded design path information based on the concretization rule.

### (Supplementary Note 9)

An information processing method comprising:
generating, for system configuration information each representing a system configuration including a combination of elements, design path information representing a design process of the system configuration information designed by converting an abstract element into a concrete element using a preset concretization rule;
generating embedded design path information in which each system configuration information of the system configuration information included in the design path information is provided with information of an element corresponding to a superordinate concept of the element included by each system configuration information;
setting, for each system configuration information of the system configuration information included in the embedded design path information, a reward for each system configuration information in accordance with whether or not the element included by each system configuration information is a concrete element; and
by using each system configuration information of the system configuration information included in the embedded design path information and the reward set for each system configuration information, generating learning data to be machine-learned for generating a model that converts the system configuration information based on the concretization rule.

### (Supplementary Note 10)

A computer program comprising instructions for causing a computer to execute processes to:
generate, for system configuration information each representing a system configuration including a combination of elements, design path information representing a design process of the system configuration information designed by converting an abstract element into a concrete element using a preset concretization rule;
generate embedded design path information in which each system configuration information of the system configuration information included in the design path information is provided with information of an element corresponding to a superordinate concept of the element included by each system configuration information;
set, for each system configuration information of the system configuration information included in the embedded design path information, a reward for each system configuration information in accordance with whether or not the element included by each system configuration information is a concrete element; and
by using each system configuration information of the system configuration information included in the embedded design path information and the reward set for each system configuration information, generate learning data to be machine-learned for generating a model that converts the system configuration information based on the concretization rule.

### DESCRIPTION OF REFERENCE NUMERALS

10 automated system design learning apparatus
11 designing unit
12 converting unit
13 reward setting unit
14 learning data generating unit
15 learning unit
20 storage device
30 input device
40 output device
100 information processing apparatus
101 CPU
102 ROM
103 RAM
104 programs
105 storage device
106 drive device
107 communication interface
108 input/output interface
109 bus
110 storage medium
111 communication network
121 designing unit
122 converting unit
123 reward setting unit
124 learning data generating unit

1. An information processing apparatus comprising:
at least one memory storing processing instructions; and
at least one processor configured to execute the processing instructions to:
generate, for system configuration information each representing a system configuration including a combination of elements, design path information representing a design process of the system configuration information designed by converting an abstract element into a concrete element using a preset concretization rule;
generate embedded design path information in which each system configuration information of the system configuration information included in the design path information is provided with information of an element corresponding to a superordinate concept of the element included by each system configuration information;
set, for each system configuration information of the system configuration information included in the embedded design path information, a reward for each system configuration information in accordance with whether or not the element included by each system configuration information is a concrete element; and
by using each system configuration information of the system configuration information included in the embedded design path information and the reward set for each system configuration information, generate learning data to be machine-learned for generating a model that converts the system configuration information based on the concretization rule.

2. The information processing apparatus according to claim 1, wherein the at least one processor is configured to execute the processing instructions to
generate, for each system configuration information of the system configuration information included in the design path information, the embedded design path information including information on the element included by each system configuration information and on an element corresponding to a superordinate concept of the element, based on inheritance relation information representing an element corresponding to a superordinate concept of an element.

3. The information processing apparatus according to claim 2, wherein the at least one processor is configured to execute the processing instructions to
show, for each system configuration information of the system configuration information included in the design path information, presence or absence of the elements in each system configuration information using an array, and generate the embedded design path information by providing the array of the elements included by each system configuration information with information of elements corresponding to superordinate concepts of the elements.

4. The information processing apparatus according to claim 1, wherein the at least one processor is configured to execute the processing instructions to:
generate the embedded design path information for each path representing a series of design processes of the system configuration information based on the design path information; and
set, for each path, the reward for each system configuration information of the system configuration information included in the embedded design path information.

5. The information processing apparatus according to claim 4, wherein the at least one processor is configured to execute the processing instructions to
in the same path, set the reward for the system configuration information in a predetermined process included in the embedded design path information and, based on the reward, set the reward for the other system configuration information.

6. The information processing apparatus according to claim 5, wherein the at least one processor is configured to execute the processing instructions to
in the same path, set the reward for the system configuration information in a last process included in the embedded design path information and, based on the reward, set the reward for the other system configuration information.

7. The information processing apparatus according to claim 5, wherein the at least one processor is configured to execute the processing instructions to
in the same path, set the largest reward set for the system configuration information in a predetermined process included in the embedded design path information, as the reward for the other system configuration information.

8. The information processing apparatus according to claim 1, wherein the at least one processor is configured to execute the processing instructions to
by using a loss based on the reward, generate the model that converts each system configuration information of the system configuration information included in the embedded design path information based on the concretization rule.

9. An information processing method comprising:
generating, for system configuration information each representing a system configuration including a combination of elements, design path information representing a design process of the system configuration information designed by converting an abstract element into a concrete element using a preset concretization rule;
generating embedded design path information in which each system configuration information of the system configuration information included in the design path information is provided with information of an element corresponding to a superordinate concept of the element included by each system configuration information;
setting, for each system configuration information of the system configuration information included in the embedded design path information, a reward for each system configuration information in accordance with whether or not the element included by each system configuration information is a concrete element; and
by using each system configuration information of the system configuration information included in the embedded design path information and the reward set for each system configuration information, generating learning data to be machine-learned for generating a model that converts the system configuration information based on the concretization rule.

10. The information processing method according to claim 9, comprising
generating, for each system configuration information of the system configuration information included in the design path information, the embedded design path information including information on the element included by each system configuration information and on an element corresponding to a superordinate concept of the element, based on inheritance relation information representing an element corresponding to a superordinate concept of an element.

11. The information processing method according to claim 10, comprising
showing, for each system configuration information of the system configuration information included in the design path information, presence or absence of the elements in each system configuration information using an array, and generating the embedded design path information by providing the array of the elements included by each system configuration information with information of elements corresponding to superordinate concepts of the elements.

12. The information processing method according to claim 9, comprising:
generating the embedded design path information for each path representing a series of design processes of the system configuration information based on the design path information; and
setting, for each path, the reward for each system configuration information of the system configuration information included in the embedded design path information.

13. The information processing method according to claim 12, comprising
in the same path, setting the reward for the system configuration information in a predetermined process included in the embedded design path information and, based on the reward, setting the reward for the other system configuration information.

14. The information processing method according to claim 13, comprising
in the same path, setting the reward for the system configuration information in a last process included in the embedded design path information and, based on the reward, setting the reward for the other system configuration information.

15. The information processing method according to claim 13, comprising
in the same path, setting the largest reward set for the system configuration information in a predetermined process included in the embedded design path information, as the reward for the other system configuration information.

16. The information processing method according to claim 9, comprising
by using a loss based on the reward, generating the model that converts each system configuration information of the system configuration information included in the embedded design path information based on the concretization rule.

17. A non-transitory computer-readable storage medium storing a program, the program comprising instructions for causing a computer to execute processes to:
generate, for system configuration information each representing a system configuration including a combination of elements, design path information representing a design process of the system configuration information designed by converting an abstract element into a concrete element using a preset concretization rule;
generate embedded design path information in which each system configuration information of the system configuration information included in the design path information is provided with information of an element corresponding to a superordinate concept of the element included by each system configuration information;
set, for each system configuration information of the system configuration information included in the embedded design path information, a reward for each system configuration information in accordance with whether or not the element included by each system configuration information is a concrete element; and
by using each system configuration information of the system configuration information included in the embedded design path information and the reward set for each system configuration information, generate learning data to be machine-learned for generating a model that converts the system configuration information based on the concretization rule.
